(19) United States
(12) Patent Application Publication
(10) Pub. No.: US 2017/0278674 A1
(43) Pub. Date: Sep. 28, 2017

(54) LOCAL DRY ETCHING APPARATUS

(71) Applicant: SPEEDFAM Co., Ltd., Ayase-city (JP)

(72) Inventor: Yasushi OBARA, Ayase-city (JP)

(73) Assignee: SPEEDFAM Co., Ltd., Ayase-city (JP)

(21) Appl. No.: 15/463,941

(22) Filed: Mar. 20, 2017

(30) Foreign Application Priority Data
Mar. 25, 2016 (JP) 2016-061803

(51) Int. Cl. H01J 37/32; H01L 21/67

(52) U.S. Cl. CPC H01J 37/3244; H01J 37/32009; H01J 37/32724; H01L 21/67069; H01J 2237/334

(57) ABSTRACT

A local dry etching apparatus includes a vacuum chamber, a nozzle opened in the vacuum chamber, a discharge tube connected to the nozzle, a workpiece table disposed in the vacuum chamber for mounting a workpiece thereon, a table driving device, a table driving control device, an electromagnetic wave oscillator, a gas supply device for supplying a raw material gas to the discharge tube, a plasma generation portion formed in the discharge tube, and an electromagnetic wave transmission unit for irradiation of electromagnetic waves oscillated in the electromagnetic wave oscillator to the plasma generation portion, in which the nozzle and the discharge tube are composed of separate parts and a temperature adjusting unit is provided for adjusting the temperature of at least one of the nozzle and the discharge tube.

### CROSS-REFERENCE TO RELATED APPLICATION

This application claims priority from Japanese Patent Application No. 2016-061803, filed on Mar. 25, 2016, which is incorporated herein by reference in its entirety.

### FIELD OF THE INVENTION

The present invention relates to a local etching apparatus of locally fabricating the surface of a workpiece such as a silicon wafer or a semiconductor wafer by dry etching.

### BACKGROUND OF THE INVENTION

FIG. 1 is an explanatory view for explaining the principle of a method of flattening a workpiece by local dry etching using plasma. An active species gas G in the plasma generated by a plasma generation portion A that constitutes a portion of a discharge tube B is injected from a nozzle N to the surface of a workpiece W. The workpiece W is mounted and fixed on a workpiece table T, and the workpiece table T is scanned at a speed and a pitch controlled in a horizontal direction relative to the nozzle N.

The workpiece W varies in thickness according to position and has fine unevenness before flattening fabrication. Before local dry etching for flattening, the thickness in each sectioned areas of the workpiece W is measured. This measurement provides the thickness data of each area, that is, position-thickness data.

In the local dry etching fabrication, a removed amount of a material in each area corresponds to a time during which the area is exposed to the active species gas G. Therefore, the relative speed of the nozzle passing the workpiece is determined such that the nozzle moves at a lower speed over a relatively thick portion Wa and at a higher speed over a relatively thin portion.

### SUMMARY OF THE INVENTION

In the local dry etching apparatus for performing such fabrication, in a case where the discharge tube and the nozzle are formed of separated parts or from different materials, a connection portion of the discharge tube and the nozzle is treated, for example, by using a sealing member such as an O ring.

When a raw material gas supplied in the discharge tube is irradiated with electromagnetic waves such as microwaves, an active species gas G is generated at a plasma generation portion A. The discharge tube generates heat by various factors, for example, dielectric loss at the discharge tube itself by the irradiation of the electromagnetic waves or degradation of the discharge tube, to cause temperature difference between the nozzle and the discharge tube. When the temperature difference occurs, it yields dimensional change due to thermal expansion of the nozzle and the discharge tube to cause problems (such as accelerated degradation of the sealing member, dusting due to friction between the nozzle and the discharge tube, vacuum break through the gap, worsening of cleanliness in the apparatus) at the connection portion of the nozzle and the discharge tube.

The present invention has been achieved in view of the situations described above and intends to mitigate various problems at the connection portion between the nozzle and the discharge tube of the local dry etching apparatus such as accelerated degradation of the sealing member, dusting due to friction between the nozzle and the discharge tube, vacuum break through the gap, worsening of cleanliness in the apparatus and perform processing at high accuracy while maintaining conditions in the constitutions of the apparatus.

The subjects described above are solved by the following means.

That is, the present invention provides, in a first aspect, a local dry etching apparatus of locally fabricating the surface of a workpiece by dry etching, the apparatus including:

a vacuum chamber,

a nozzle opened in the vacuum chamber,

a discharge tube connected to the nozzle,

a workpiece table disposed in the vacuum chamber for mounting a workpiece thereon,

a table driving device for driving the workpiece table,

a table driving control device for controlling the table driving device,

an electromagnetic wave oscillator,

a gas supply device for supplying a raw material gas to the discharge tube,

a plasma generation portion formed to the discharge tube, and

an electromagnetic wave transmission unit for irradiation of electromagnetic waves oscillated by the electromagnetic wave oscillator to the plasma generation portion,

in which

the nozzle and the discharge tube are formed of separate parts, and, further,

a temperature adjusting unit is provided for adjusting the temperature of at least one of the nozzle and the discharge tube.

The present invention provides, in a second aspect, the local dry etching apparatus according to the first aspect, wherein the temperature adjusting unit is provided to the nozzle.

The present invention provides, in a third aspect, the local dry etching apparatus according to the second aspect, wherein a temperature control device is provided for controlling the temperature of the temperature adjusting unit provided to the nozzle.

The present invention provides, in a fourth aspect, the local dry etching apparatus according to the second aspect, wherein the temperature adjusting unit is attached directly to the nozzle.

The present invention provides, in a fifth aspect, the local dry etching apparatus according to the second aspect, wherein the temperature adjusting unit is attached indirectly to the nozzle.

The present invention provides, in a sixth aspect, the local dry etching apparatus according to the first aspect, wherein the temperature adjusting unit is disposed to each of the nozzle and the discharge tube.

The present invention provide, in a seventh aspect, the local dry etching apparatus according to the sixth aspect, wherein a temperature control device is provided for individually controlling the temperature of the temperature adjusting unit disposed to each of the nozzle and the discharge tubes.

According to an aspect of the present invention, since the temperature adjusting unit is provided to at least one of the nozzle and the discharge tube, it is possible to mitigate the problems caused by the difference of thermal expansion due to the temperature difference between the nozzle and the discharge tube formed of separate parts or from different materials, such as accelerated degradation of the sealing member, dusting due to friction between the nozzle and the discharge tube, vacuum break through the gap, worsening of cleanliness in the apparatus at the connection portion between the nozzle and the discharge tube, and perform processing at high accuracy while maintaining conditions for the constitutions of the apparatus.

### BRIEF DESCRIPTION OF THE DRAWINGS

FIG. 1 is an explanatory view for explaining the principle of a method of flattening a workpiece by local dry etching using plasma;

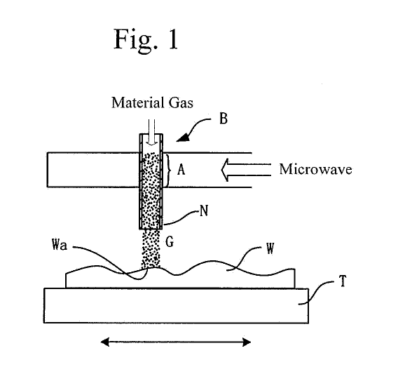

FIG. 2 is a cross sectional view illustrating the outline and a first embodiment of a local dry etching apparatus according to the present invention;

FIG. 3 is a cross sectional view illustrating a second embodiment of the local dry etching apparatus according to the present invention;

FIG. 4 is a cross sectional view illustrating a third embodiment of the local dry etching apparatus according to the present invention; and

FIG. 5 is a cross sectional view illustrating a fourth embodiment of the local dry etching apparatus according to the present invention.

### DETAILED DESCRIPTION OF THE INVENTION

Preferred embodiments of the present invention are to be described below with reference to the drawings.

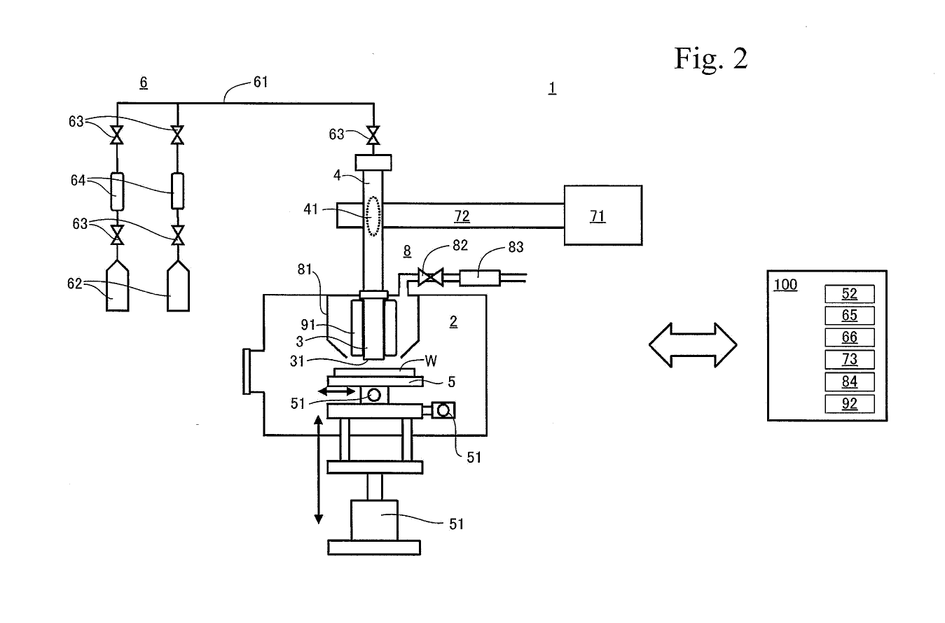

FIG. 2 is a cross sectional view illustrating the outline and a first embodiment of a local dry etching apparatus 1 of the present invention. The local dry etching apparatus 1 has a vacuum chamber 2. A not illustrated vacuum pump is attached to the vacuum chamber 2 and the inside of the vacuum chamber 2 can be evacuated by the vacuum pump.

A nozzle 3 is provided in the vacuum chamber 2, and the nozzle 3 is attached to the vacuum chamber 2 with an injection port 31 as the opening of the nozzle 3 being opposed to a workpiece W. A discharge tube 4 is connected on the side opposite to the injection port 31 of the nozzle 3.

A workpiece table 5 for mounting a workpiece W thereon is disposed in the vacuum chamber 2. A table driving device 51 is provided for driving the workpiece table 5 in the planar direction and the vertical direction. A table driving control device 52 is provided outside of the vacuum chamber 2 for controlling the table driving device 51.

A raw material gas is supplied from a gas supply device 6 to the discharge tubes 4. A plasma generation portion 41 is provided to the discharge tube 4. The plasma generation portion 41 constitutes a portion of the discharge tube 4.

Electromagnetic waves (for example, microwaves) oscillated by an electromagnetic wave oscillator 71 are introduced by way of an electromagnetic wave transmission unit 72 to the plasma generation portion 41 and the raw material gas passing the inside of the discharge tube 4 is converted into plasma by irradiation of the electromagnetic waves. The electromagnetic wave oscillator 71 is controlled by an electromagnetic wave oscillation control device 73.

The gas supply device 6 includes a plurality of material gas reservoirs 62 filled with different kinds of raw material gases, for example, gases such as SF6, NF3, and CF4, valves 63 for turning on and off the supply of the raw material gases, mass flow controllers 64 for controlling flow rates, and a supply pipe 61 for connecting them and introducing the gases to the flow inlet of the discharge tube 4. The valves 63 and the mass flow controllers 64 are controlled by a valve control device 65 and a mass flow controller control device 66.

At the periphery, the nozzle 3 has an exhaust duct 81 disposed so as to surround the periphery of the nozzle 3, and an exhaust valve 82 and an exhaust pump 83 connected to the exhaust duct 81 as the exhaust unit 8. The reaction gas generated by local dry etching is exhausted by the exhaust pump 83 to the outside of the vacuum chamber 2. Operations of the exhaust valve 82 and the exhaust pump 83 are controlled by an exhaust control device 84.

A temperature adjusting unit 91 is provided along the outer periphery of the nozzle 3. The temperature of the temperature adjusting unit 91 is properly adjusted to a desired temperature by a temperature control device 92. An embodiment for the temperature adjustment of the nozzle 3 by the temperature adjusting unit 91 is to be described later.

Further, the temperature control unit 92 constitutes an element of a main control device 100 together with the table driving control device 52, the valve control device 65, the mass flow controller control device 66, the electromagnetic wave oscillator control device 73 and the exhaust control device 84. Each of the connection line between the constitutions and the relevant control devices in the main control device 100 is not illustrated.

In the local dry etching fabrication of the workpiece according to the invention, thickness in each of the sectioned area (unevenness profile) is measured in advance for every workpiece W. Based on the data for the thickness at the position of each of the areas, that is, position-thickness data obtained by the measurement, the processing recipes are prepared. Local dry etching fabrication using the nozzle 3 and the discharge tube 4 is to be shown below.

The position-thickness data of the workpiece is assumed to have been obtained already. First, the workpiece W is loaded and mounted on the workpiece table 5 in the vacuum chamber 2 and the vacuum chamber 2 is evacuated. Alternatively, the workpiece W is loaded and mounted from a transport chamber (not illustrated) which is provided adjacent to the already evacuated vacuum chamber 2.

Then, the valve 63 of the gas supply device 6 is opened and the raw material gas in the material gas reservoir 62 is supplied into the discharge tube 4 by way of the supply pipe 61. In this example, on/off of the valve 63 and the mass flow controller 64 are controlled by the valve control device 65 and the mass flow controller control device 66, respectively. Concurrently, electromagnetic waves are oscillated by the electromagnetic wave oscillator 71. The oscillated electromagnetic waves are transmitted through the electromagnetic wave transmission unit 72 and introduced to the discharge tube 4.

When the plasma generation portion 41 of the discharge tube 4 is irradiated with the electromagnetic waves, the raw material gas passing through the inside of the discharge tube 4 is converted into plasma to form an active species gas. The thus formed active species gas proceeds to the injection port 31 of the nozzle 3 and injected therefrom to the surface of the workpiece W. By driving the table driving device 51, the workpiece table 5 on which the workpiece is mounted, is moved relatively such that the injection port 31 scans the workpiece W.

The scanning speed when the nozzle 3 relatively moves in each of the sectioned areas of the workpiece is controlled such that the workpiece surface is planarized in accordance with the uneven profile. Local dry etching is performed as described above.

FIG. 2 illustrates the first embodiment of the local dry etching apparatus 1 according to the present invention. A temperature adjusting unit 91 is provided to the outside of the nozzle 3. The temperature adjusting unit 91 may be provided so as to act entirely or partially to the outer circumferential surface of the nozzle 3. The temperature of the temperature adjusting unit 91 is properly adjusted by a temperature control device 92.

For the adjustment of the temperature of the nozzle 3 by the temperature adjusting unit 91, thermal expansion of the discharge tube 4 caused by various factors such as plasma conversion of the raw material gas, dielectric loss at the discharge tube itself with irradiation of the electromagnetic waves, and degradation of the discharge tube is calculated in advance. Then, the temperature of the nozzle 3 is calculated so as to give the thermal expansion of the nozzle 3 that corresponds to the thermal expansion of the discharge tube 4 by utilizing previously calculated thermal expansion coefficient of the nozzle 3, and the temperature of the nozzle 3 is adjusted to the calculated temperature with the temperature adjusting unit 91 controlled by the temperature control device 92.

Alternatively, the temperature of the nozzle 3 may be adjusted by measuring the temperature of the discharge tube 4 at a desired timing by a temperature sensor, calculating the thermal expansion of the discharge tube 4 in real time based on the measurement result, calculating the temperature of the nozzle 3 to give a thermal expansion of the nozzle 3 that corresponds to the thermal expansion of the discharge tube 4 by utilizing previously calculated expansion coefficient of the nozzle 3, and the temperature of the nozzle 3 is adjusted to the calculated temperature with the temperature adjusting unit 91 controlled by the temperature control device 92.

Since the nozzle 3 under the proper temperature control expands or shrinks in alignment with the expansion or shrinkage of the discharge tube 4 due to the temperature change, neither misalignment nor gap is caused at the connection portion between the nozzle 3 and the discharge tube 4, so that accelerated degradation of the sealing member, dusting, vacuum leakage and worsening of the cleanliness in the apparatus at the connection portion can be controlled to attain a local dry etching apparatus excellent in the processing stability at high accuracy.

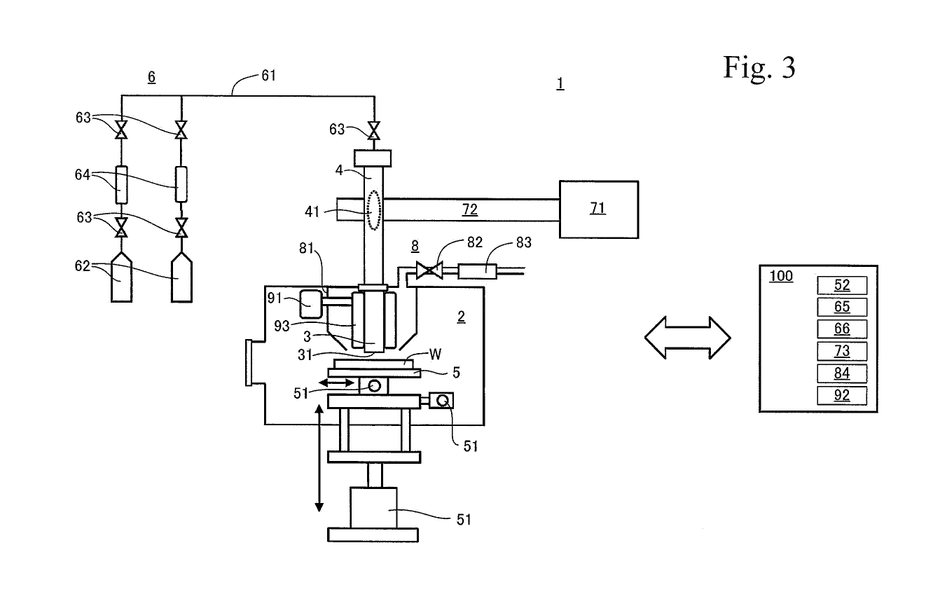

FIG. 3 is a cross sectional view illustrating a second embodiment of the local dry etching apparatus 1 of the present invention. The nozzle 3 is provided with a thermal conductor 93 that acts on the outer side of the nozzle. The thermal conductor 93 may be provided so as to act entirely or partially to the outer periphery of the nozzle 3. The thermal conductor 93 is connected to the temperature adjusting unit 91. This example is an embodiment in which the temperature adjusting unit 91 is attached indirectly to the nozzle 3.

In addition to the advantageous effect obtained by the first embodiment, in a case where it is structurally difficult to provide the temperature adjusting unit 91 directly to the nozzle 3 by the presence of a structure, for example, an exhaust dust 81 at the periphery of the nozzle 3 in the vacuum chamber 2, the temperature of the nozzle 3 can be adjusted by providing the thermal conductor 93 to the outside of the nozzle 3, connecting the temperature adjusting unit 91 to the thermal conductor 93 and adjusting the temperature of the temperature adjusting unit 91. The temperature of the temperature adjusting unit 91 is properly adjusted by a temperature control device 92. Since the temperature adjusting method and other constitutions are identical with those of the first embodiment described above, explanation therefor is omitted.

As described above, by adjusting the temperature of the nozzle indirectly by the temperature adjusting unit 91 by way of the thermal conductor 93, the temperature of the nozzle 3 can be adjusted reliably even in an apparatus of a structure where the temperature adjusting unit 91 is difficult to be provided in the vacuum changer 2. Further, since the temperature adjusting unit 91 is attached indirectly to the nozzle 3, exchange or maintenance of the temperature adjusting unit 91 can be facilitated.

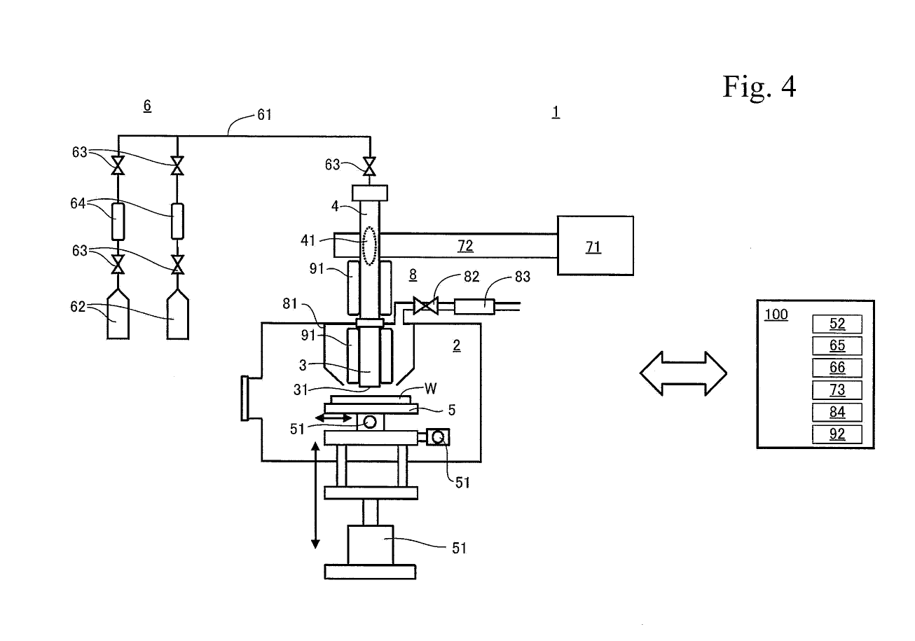

FIG. 4 is a cross sectional view illustrating a third embodiment of the local dry etching apparatus 1 according to the present invention. Temperature adjusting units 91 are provided to the outside of the nozzle 3 and that of the discharge tube 4. Each of the temperature adjusting units 91 may be provided so as on act entirely or partially to the outer periphery of the nozzle 3 and the discharge tube 4. Each of the temperature of the temperature adjusting units 91 is properly adjusted by a temperature control device 92.

The method of adjusting the temperature is basically identical with that of the first embodiment described above. For adjusting the temperature of the nozzle 3 and the discharge tube 4 by the temperature adjusting unit 91, thermal expansion coefficients of the nozzle 3 and the discharge tube 4 generated due to various factors such as plasma conversion of the raw material gas, dielectric loss at the discharge tube itself with irradiation of electromagnetic waves and degradation of the discharge tube due to are calculated in advance and the temperatures of the nozzle 3 and the discharge tube 4 are adjusted by individually controlling the temperatures of each of the temperature adjusting units 91 by the temperature control device 92 so as to match the thermal expansion of the nozzle 3 and the discharge tube 4. The temperature of the nozzle 3 and the discharge tube 4 may be adjust properly while taking fabrication characteristics and degradation rate of apparatus components into consideration.

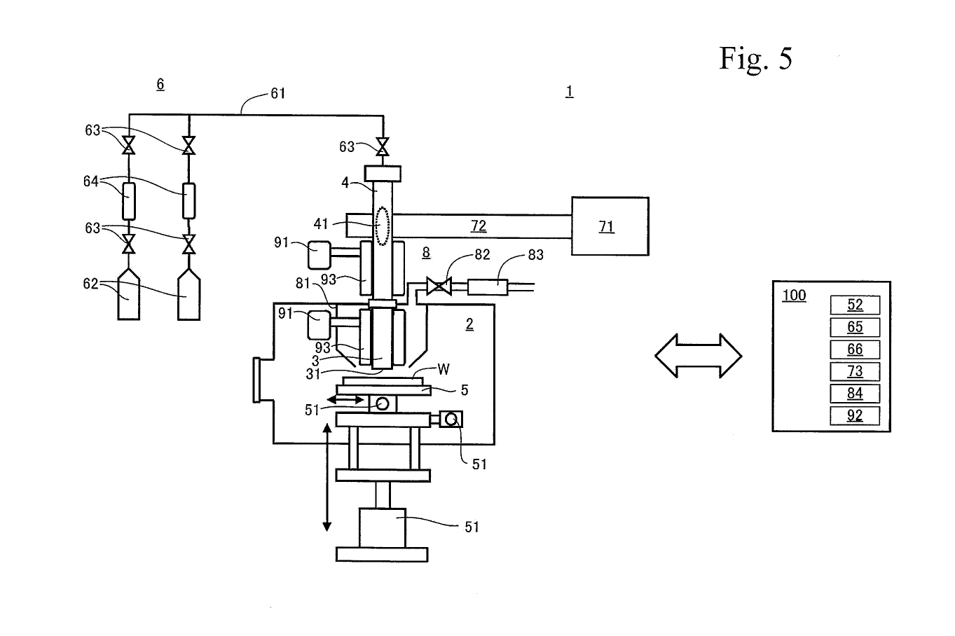

FIG. 5 is a cross sectional view illustrating a fourth embodiment of the local dry etching apparatus 1 of the present invention. Thermal conductors 93 are disposed to the outside of the nozzle 3 and that of the discharge tube 4. Each of the thermal conductors 93 may be provided so as to act entirely or partially to the outer periphery of the nozzle 3 and the discharge tube 4. The thermal conductor 93 is connected to a temperature adjusting unit 91. The temperature of the temperature adjusting unit 91 is properly adjusted by a temperature control device 92.

In a case where it is structurally difficult to provide the temperature adjusting unit 91 directly to the periphery of the nozzle 3 and the discharge tube 4, for example, by the presence of a structure at the periphery of the nozzle 3 and the discharge tube 4, the temperature of the nozzle 3 and that of the discharge 4 can be adjusted by providing the thermal conductors 93 to the outside of the nozzle 3 and that of the discharge tube 4 and connecting a temperature adjusting unit 91 to each of the thermal conductors 93. The temperature of the temperature adjusting unit 91 is properly adjusted by the temperature control device 92. Since the method of adjusting the temperature and other constitutions are identical with those of the third embodiment described above, explanation therefor is to be omitted.

As described above also in an apparatus of the structure where the temperature adjusting unit 91 is difficult to be provided, the temperature of the nozzle 3 and that of the discharge tube 4 can be adjusted reliably by indirectly adjusting the temperature of the nozzle 3 and the discharge tube 4 by the temperature adjusting units 91 by way of the neat conductor 93. Further, since the temperature adjusting units 91 are attached indirectly to the nozzle 3 and the discharge tube 4, exchange or maintenance of the temperature adjusting units 91 can be facilitated.

In addition to the third and the fourth embodiments disclosed above, the present invention may also be embodied such that the temperature adjusting unit 91 provided to one of the nozzle 3 and the discharge tube 4 is attached directly, while the temperature adjusting unit 91 provided to the other of them is attached indirectly.

In each of the embodiments described above, the temperature of at least one of the nozzle 3 and the discharge tube 4 may be adjusted by the temperature adjusting unit 91 at the timing either during processing or in the interval between successive fabrications of local dry etching, and the temperature may be adjusted by heating or cooling.

While the temperature of the temperature adjusting unit 91 is controlled by the temperature control unit 92 based on the expansion coefficients calculated in advance and the actually measured temperatures of the nozzle 3 and the discharge tube 4, it may be conveniently set by merely giving a certain constant heat.

Further, any constitution may be adopted for the temperature adjusting unit 91 so long as the unit has a temperature adjustable function. For example, temperature adjusting means such as fluid, heater wire, optical unit, laser, etc. can be used.

Further, the present invention is applicable also to an apparatus having plural sets of nozzles 3 and the discharge tubes 4 in a single vacuum chamber 2. In such a constitution, the temperature adjusting unit 91 may be disposed individually to each of the sets, or the temperature adjustment can be performed by using the temperature adjusting units 91 in common, or connecting thermal conductors 93 between a plurality of sets.

What is claimed is:

1. A local dry etching apparatus of locally fabricating the surface of a workpiece by dry etching, the apparatus comprising:
a vacuum chamber,
a nozzle opened in the vacuum chamber,
a discharge tube connected to the nozzle,
a workpiece table disposed in the vacuum chamber and mounting a workpiece thereon,
a table driving device for driving the workpiece table,
a table driving control device for controlling the table driving device,
an electromagnetic wave oscillator,
a gas supply device for supplying a raw material gas to the discharge tube,
a plasma generation portion formed to the discharge tube, and
an electromagnetic wave transmission unit for irradiation of electromagnetic waves oscillated by the electromagnetic wave oscillator to the plasma generation portion,
in which
the nozzle and the discharge tube are formed of separate parts, and
a temperature adjusting unit is provided for adjusting the temperature of at least one of the nozzle and the discharge tube.

2. The local dry etching apparatus according to claim 1,
wherein
the temperature adjusting unit is provided to the nozzle.

3. The local dry etching apparatus according to claim 2,
wherein
a temperature control device is provided for controlling the temperature of the temperature adjusting unit provided to the nozzle.

4. The local dry etching apparatus according to claim 2,
wherein
the temperature adjusting unit is attached directly to the nozzle.

5. The local dry etching apparatus according to claim 2,
wherein
the temperature adjusting unit is attached indirectly to the nozzle.

6. The local dry etching apparatus according to claim 1,
wherein
the temperature adjusting unit is disposed to each of the nozzle and the discharge tube.

7. The local dry etching apparatus according to claim 6,
wherein
a temperature control device is provided for individually controlling the temperature of the temperature adjusting unit disposed to each of the nozzle and the discharge tubes.
